(19) United States
(12) Patent Application Publication
(10) Pub. No.: US 2006/0132340 A1
(43) Pub. Date: Jun. 22, 2006

(54) Apparatus and method for time-to-digital conversion and jitter-measuring apparatus using the same

(76) Inventor: Chun Wei Lin, Changhua (TW)

Correspondence Address: VOLENTINE FRANCOS & WHITT, PLLC;ONE FREEDOM SQUARE, SUITE 1260, 11951 FREEDOM DRIVE, RESTON, VA, 20190, US

(21) Appl. No.: 11/305,168

(22) Filed: Dec. 19, 2005

(30) Foreign Application Priority Data
Dec. 22, 2004 (TW) 093139980

(51) Int. Cl. H03M 1/10

(52) U.S. Cl. 341/120

(57) ABSTRACT

A time-to-digital conversion apparatus reduces the pulse width of a signal to be tested by introducing the signal through a plurality of shrinking cells cascaded until the reduced pulse width cannot drive the next shrinking cell, to generate a group of digital output codes representative of a binary code. The apparatus operates with a clock signal and comprises a shrinking cell group converting the signal to be tested to a plurality of first digital output codes, and a latch cell group receiving the first digital output codes and generating a plurality of second digital output codes which can be converted to a binary code. The time-to-digital conversion apparatus could be utilized in a jitter-measuring apparatus, which converts the jitter of a signal of analog form to a group of digital codes. The digital codes represent a time width of cycle-to-cycle jitter of the signal.

### BACKGROUND OF THE INVENTION

1. Field of the Invention

The present invention relates to an apparatus and a method for time-to-digital conversion, particularly to an apparatus and a method based on the pulse width reduction, which is particularly suitable for counting the tiny time intervals. Furthermore, the present invention relates to a jitter-measuring apparatus, more particularly to a jitter-measuring apparatus based on the apparatus for time-to-digital conversion, which is particularly suitable for measurement of high-speed jitters.

2. Description of the Related Art

The time-to-digital converter (TDC) is used widely in many fields including time domain reflectometer for measuring the reflection condition in signal paths, a radar for military searches, a semiconductor analyzer for measuring the timing relation in the integrated circuit industry, a precision instrument for measuring a variety of physics phenomena, a laser range finder, an analog-to-digital converter, and counters for measuring tiny time differences. In general, there are three design methods of time-to-digital converters. (1) Dual slope method: charging and discharging a single capacitor to find the characteristics of the capacitor to determine the gain ratio of TDC. However, due to the instability induced from the capacitance variation by the environment, the precision is affected and this method has the drawbacks of an excessive gain ration, a long conversion time and a prolonged recovery time for the next measurement. (2) Time-to-amplitude conversion method: A capacitor is charged by a current source and the variation in charge with respect to the voltage changed is recorded. The voltage is converted into a digital signal for obtaining the relation between time and digital signal. The advantage of this method is high processing speed, but the precision is still limited by the stability of the capacitor. (3) Unit delay buffer method: A certain time interval delay is obtained by a plurality of digital buffers connected in series. After predetermined pulses are inputted, a tiny time difference is identified to form the output signal of each buffer and the object of measurement is achieved. However, the circuit designed by this method is complicated and the potential jitters occurring in each buffer will have a large effect on the precision of the measurement.

A jitter is defined as the time deviation from its ideal position of a signal edge, and is usually called a timing distortion. The jitter may result from thermal noises, electromagnetic noises, circuit instability or transmission loss. For a data transmission system, the jitter will cause errors of data transmission and then degrade the reliability of the system.

There are two kinds of jitters. One is a deterministic jitter and another is a random jitter. A deterministic jitter, which is a Gaussian distribution in nature, results from the factors of thermal noises and shot noises, etc. The deterministic jitter comprises the following components of periodic jitter (PJ), data dependent jitter (DDJ) and duty cycle distortion (DCD), etc. PJ is usually in sinusoidal form, DDJ is usually caused by inter-symbol interference (ISI) of system bandwidth limitation and DCD comes from the voltage offset between differential signals and the time difference of the rising and falling of a system. A total jitter is the superposition of deterministic jitter and random jitter.

In general, the methods for jitter measurement include an eye diagram and time interval error (TIE). Both of them provide the related information of total jitter. Other methods such as spectrum analysis will provide individual information for each jitter component.

FIG. 1 shows an eye diagram 15, which is obtained by a high-speed oscilloscope to capture and superpose each falling edge and each rising edge 11 of a series of pulses. A larger eye opening (EO) represents better data transmission quality. On the contrary, a narrower eye opening stands for worse data transmission quality. The quality of data transmission could be determined and verified by comparing the mask 12 of FIG. 1 with an ideal eye diagram.

TIE statistics diagram provides the error between an actual time position and an ideal time position, and the divergences caused by deterministic jitter and random jitter.

For jitter measurement, however, it is impossible to find an exactly ideal reference signal generator; a false phenomenon may result from a magnified measurement value including extra-induced jitters, as shown in FIG. 2. In addition, the statistical characteristic of signal jitters is difficult to converge, and that easily causes measurement loss. As to hardware implementation of jitter measurement, there are many limitations on the design and manufacturing of high-speed signals. For example, after a high-speed signal passes through an inverter chain, the inverted signal cannot respond in time, but is delayed, and then makes signals that are hard to identify. Therefore, it is necessary to make a breakthrough in measuring jitters precisely in low-speed conditions.

### SUMMARY OF THE INVENTION

The primary objective of the present invention is to provide an apparatus and a method of time-to-digital conversion, which is based on shrinking cells but not charging and discharging capacitors, to convert a signal to be tested to a binary code without the influence of capacitors. The secondary objective of the present invention is to provide a jitter-measuring apparatus using the apparatus of time-to-digital conversion, which converts jitters of a signal of analog form to a group of digital codes. The digital codes represent a time width of cycle-to-cycle jitter of the signal.

In order to achieve the objective, the present invention discloses a time-to-digital conversion apparatus comprising a shrinking cell group and a latch cell group. The shrinking cell group includes a plurality of shrinking cells, which are connected in series to form a multi-stage shrinking cell. The shrinking cell receives a signal to be tested with a pulse width. After the signal to be tested passes each shrinking cell, the pulse width of the signal to be tested is reduced by a resolution until the pulse width cannot drive the next shrinking cell. Each shrinking cell generates a first digital output code. The latch cell group includes as many latch cells as shrinking cells. Each latch cell is connected to the corresponding shrinking cell to receive and latch the first digital output from the corresponding shrinking cell to generate a second digital output code. The second digital output codes are expressed in a thermometer code.

The second digital output codes are sent to a priority encode and an output latch unit for post-treatment. The priority encoder converts the second digital output codes to a binary code. The output latch unit latches the binary code and outputs the binary code when receiving a trigger signal, which is synchronized with a second clock signal.

The method of time-to-digital conversion comprises the steps of: (1) shrinking a pulse width of a signal to be tested successively by a resolution to generate a plurality of first digital output codes; (2) converting the plurality of the first digital output codes to a plurality of second digital output codes by a latch treatment and (3) converting the plurality of second digital output codes to at least one third digital output code which is a binary code.

The first embodiment of the jitter-measuring apparatus of the present invention, which operates with a first clock signal, is used to convert a first signal, which is synchronized with the first clock signal and of a first pulse width, to a binary code. The jitter-measuring apparatus comprises an input controller dividing the frequency of the first clock signal by an odd number down to a second clock signal and generating a third clock signal with a time delay to the second clock signal; a sample and hold circuit, which operates with the level of the third clock signal, converting a first signal with a first pulse width to a second signal with a second pulse width; a pulse modulation unit, which operates with a threshold, converting the second signal to a third signal with a third pulse width; a pulse shrinking unit converting the third signal with the third pulse width to a fourth signal with a fourth pulse width; a time-to-digital conversion apparatus converting the fourth signal to at least one second digital output code, and a latch controller using the second clock signal from the input controller to generate a reset signal to the latch cells of the time-to-digital conversion apparatus to clear the contents of the latch cells.

The second embodiment of the jitter-measuring apparatus of the present invention is used to convert a first signal to a binary code without any clock signal. The jitter-measuring apparatus comprises an input controller converting the first signal with a first pulse width to a sample and hold control signal (hereinafter S/H control signal); a sample and hold circuit, which operates with the S/H control signal, converting the first signal to a second signal with a second pulse width; a pulse modulation unit, which operates with a threshold, converting the second signal to a third signal with a third pulse width; an adjustable pulse shrinking unit converting the third signal to a fourth signal with a fourth pulse width; a time-to-digital conversion apparatus converting the fourth signal to at least one second digital output code, and a latch controller using a first control signal from the adjustable pulse shrinking unit to generate a reset signal to the latch cells of the time-to-digital conversion apparatus to clear the contents of the latch cells.

### BRIEF DESCRIPTION OF THE DRAWINGS

The invention will be described according to the appended drawings in which:

FIG. 1 shows an eye diagram used in prior arts;

FIG. 2 shows a measurement method of jitter signals of prior arts;

FIG. 3 shows an illustration of time-to-digital conversion apparatus of the present invention;

FIG. 4 shows an illustration of a circuit of a shrinking cell;

FIG. 5 shows an illustration of the shrinking of the pulse width after each shrinking cell;

FIG. 6 shows the relationship between the resolution and the control signal;

FIG. 7 shows a priority encoder and an output latch unit, which are included in the time-to-digital conversion apparatus of the present invention;

FIG. 8(a) shows a timing chart of signals inside the input controller;

FIG. 8(b) shows an embodiment of the circuit of the input controller;

FIG. 9 shows a block diagram of the first embodiment of the jitter-measuring apparatus of the present invention;

FIG. 10(a) shows an illustration of the sample and hold circuit;

FIG. 10(b) shows a timing chart of signals regarding the sample and hold circuit;

FIGS. 11(a) and 11(b) illustrate the threshold values of a data signal;

FIGS. 12(a) and 12(b) are two embodiments of the circuit and the corresponding timing chart of the pulse modulation unit of the jitter-measuring apparatus of the present invention;

FIG. 13(a) shows an embodiment of the circuit of the pulse shrinking unit of the jitter-measuring apparatus of the present invention;

FIG. 13(b) shows a timing chart of signals regarding the pulse shrinking unit of the jitter-measuring apparatus of the present invention;

FIG. 13(c) shows a magnification of N area in FIG. 13(b);

FIG. 14 shows signals regarding the first embodiment of the jitter-measuring apparatus of the present invention;

FIG. 15 shows a block diagram of the second embodiment of the jitter-measuring apparatus of the present invention;

FIG. 16 shows signals regarding the second embodiment of the jitter-measuring apparatus of the present invention;

FIG. 17(a) illustrates one embodiment of an adjustable pulse shrinking unit; and

FIG. 17(b) shows a circuit of one embodiment of FIG. 17(a).

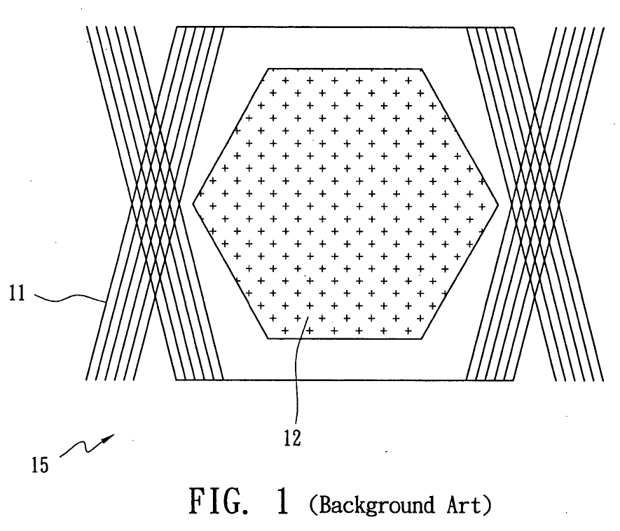

### PREFERRED EMBODIMENT OF THE PRESENT INVENTION

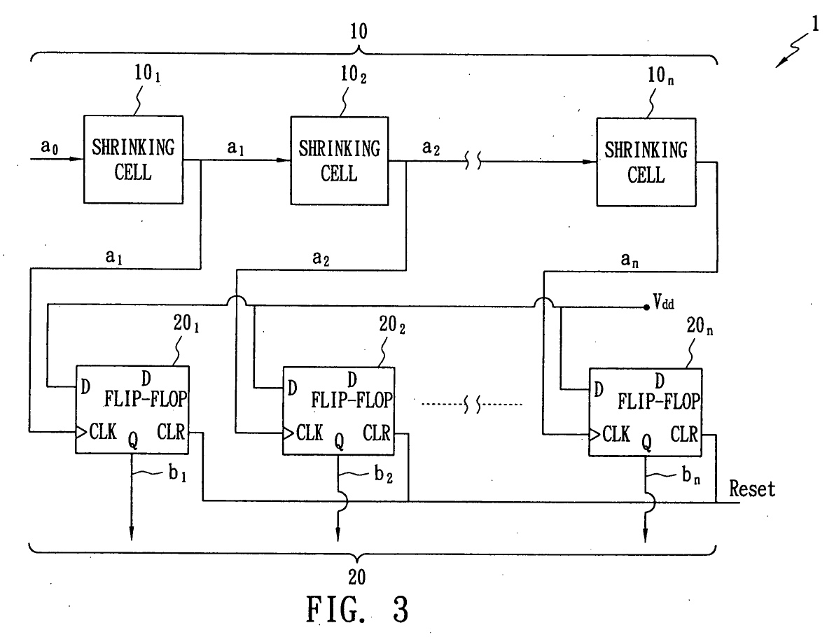

FIG. 3 shows an illustration of the time-to-digital conversion apparatus of the present invention. The time-to-digital conversion apparatus comprises a shrinking cell group 10 and a latch cell group 20. The shrinking cell group 10 includes at least one shrinking cell 10ᵢ (i: a positive integer from 1 to n), which is cascaded in order to form a multi-state shrinking cell. The shrinking cell group 10 is used to receive a signal a₀ to be tested with a pulse width w. The pulse width w of signal a₀ is reduced by a resolution r when passing each shrinking cell 10ᵢ. That is, the pulse width w is reduced to w-r, after the input signal a₀ passes a shrinking cell 10ᵢ, and the pulse width is reduced to w-2r, after the input signal a₀ passes two shrinking cells 10ᵢ₊₁. The width pulse continues to decrease until it cannot drive the next shrinking cell 10ᵢ₊₁. During the above process, each shrinking cell 10ᵢ generates a first digital output code aᵢ (i: a positive integer from 1 to n), which acts as an input to the next shrinking cell 10ᵢ₊₁. The level of each first digital output code aᵢ could be “1” (high level) or “0” (low level). The latch cell group 20 includes as many latch cells as shrinking cells. Each latch cell 20ᵢ (i: a positive integer from 1 to n) receives the corresponding first digital output code aᵢ from the corresponding shrinking cell 10ᵢ to generate a second digital output code bᵢ (i: a positive integer from 1 to n), which is on the same level as the corresponding first digital output code aᵢ. An embodiment in FIG. 3 shows a plurality of D-FF (D type flip-flop) acts as the latch cells 20ᵢ, wherein the input port D of each D-FF is connected to a source voltage V_{dd} and the clock port of each D-FF is connected to the corresponding first digital output code aᵢ. The second digital output codes bᵢ are stored in the latch cells 20ᵢ in the form of thermometer code. Before operation of the latch cell group 20, a rest signal Reset, which is synchronized with the second clock signal, is sent to the plural D-FFs to clear the contents of the plural D-FFs.

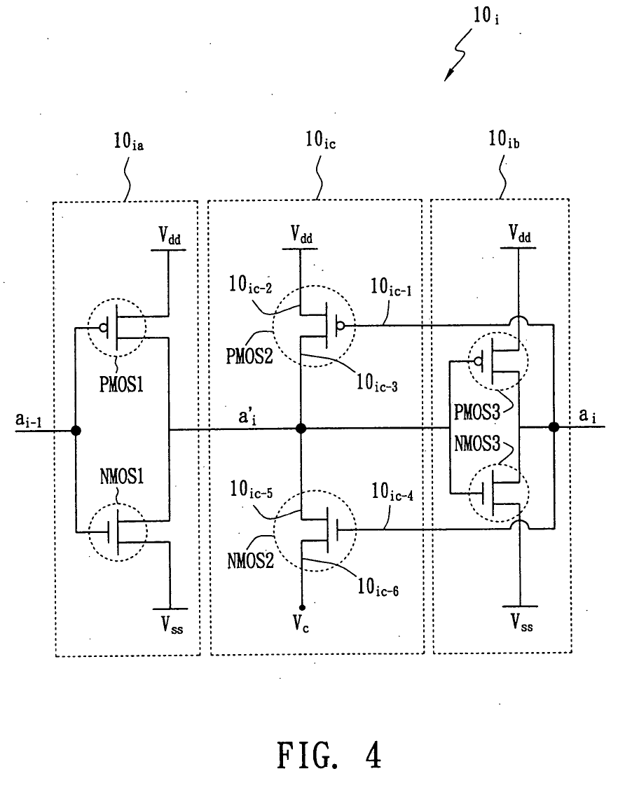

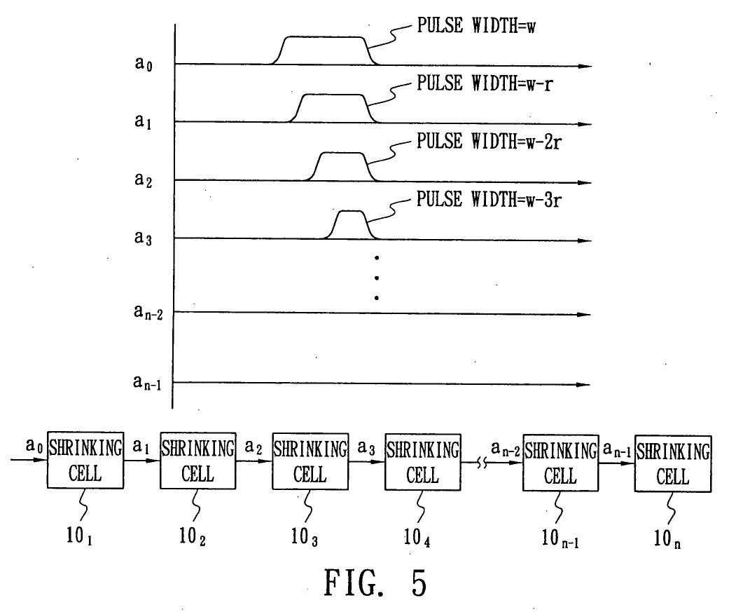

FIG. 4 shows an illustration of the circuit of a shrinking cell 10ᵢ (i: a positive integer from 1 to n). The shrinking cell 10ᵢ is utilized to reduce the pulse width w of a signal by a resolution r. The shrinking cell 10ᵢ comprises a first CMOS inverter 10ᵢₐ receiving an input signal a₁₋₁ to generate a middle signal a′ᵢ; a second CMOS inverter 10_{ib} receiving the middle signal a′ᵢ to generate an output signal aᵢ, which is an input to the next shrinking cell aᵢ₊₁ (not shown in FIG. 4), and an adjustment unit 10_{ic} receiving the middle signal a′ᵢ and the output signal aᵢ, receiving a control signal Vc to adjust the resolution r. For the first shrinking cell 10₁ of the shrinking cell group 10, the signal a₀ to be tested is the input to the first shrinking cell 10₁. The adjustment unit 10_{ic} includes a PMOS (PMOS2) and a NMOS (NMOS2). The PMOS2 uses a first terminal 10_{ic-1} to receive the output signal aᵢ, a second terminal 10_{ic-2} to connect to a power source V_{dd} and a third terminal 10_{ic-3} to receive the middle signal a′ᵢ. The NMOS2 uses a fourth terminal 10_{ic-4} to connect to the first terminal 10_{ic-1} and to receive the output signal aᵢ, a fifth terminal 10_{ic-5} to connect to the third terminal 10_{ic-3} and to receive the middle signal a′ᵢ and a sixth terminal 10_{ic-6} to receive the control signal Vc. The relationship between the input signal aᵢ₋₁ and the input signal aᵢ is shown in FIG. 5.

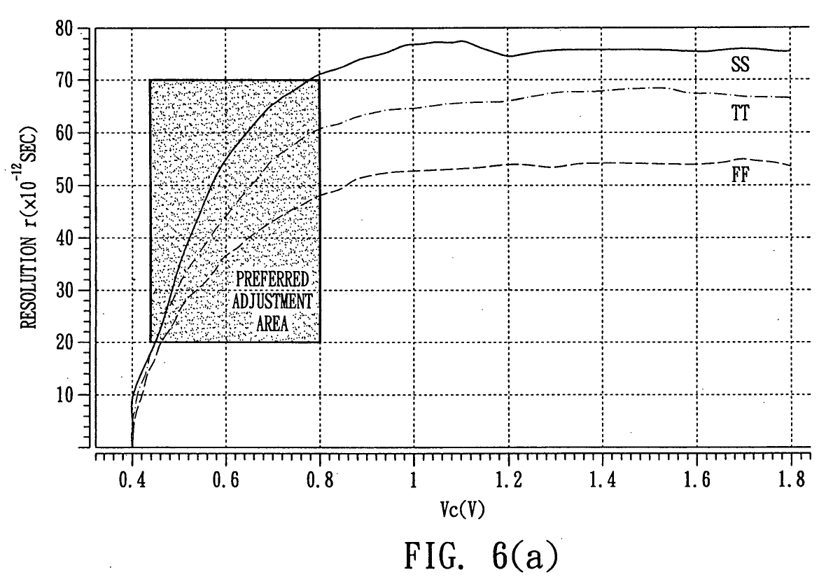

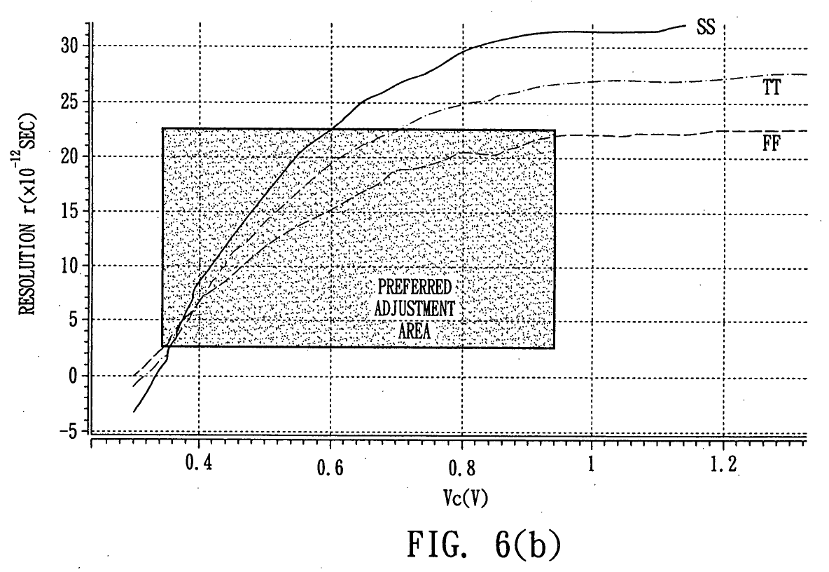

FIG. 5 shows an illustration of the shrinking of the pulse width w of the signal a₀ after each shrinking cell 10ᵢ. Although the pulse widths of signals a₁, a₂, a₃ . . . decrease by a resolution r after passing each shrinking cell 10ᵢ, the level of the signal aᵢ still remains high. The pulse width is reduced successively by a resolution r until it cannot drive the next shrinking cell. FIG. 6(a) shows the relationship between the resolution r and the control signal Vc. SS, TT and FF represent three curves obtained in three different process conditions of the shrinking cell 10ᵢ. As to a given curve, when in operation, the resolution r can be adjusted by the control signal Vc. As to plural curves (only three curves are shown in FIG. 6(a)), when in operation, the deviation of resolution r could be avoided by properly adjusting the control signal Vc. In the embodiment in FIG. 6(a), the preferred adjustment area is represented by a shaded area, where the preferred range of the control signal Vc is from 0.44V to 0.8V, and the corresponding resolution r is from 20×10⁻¹² to 70×10⁻¹² second. To obtain a smaller resolution r, when designing the shrinking cells 10ᵢ, we can select the PMOS2 and NMOS2, which are physically smaller than PMOS1, PMOS3, NMOS1 and NMOS3. That is, PMOS2 and NMOS 2 have smaller critical dimensions. FIG. 6(b) shows the relationship between the resolution r and the control signal Vc, where the resolution r can be adjusted below 10×10⁻¹² seconds, which is smaller than that in FIG. 6(a) and the preferred range of the control signal Vc is from 0.34V to 0.94V, and the corresponding resolution r is from 3×10⁻¹² to 26×10⁻¹² second.

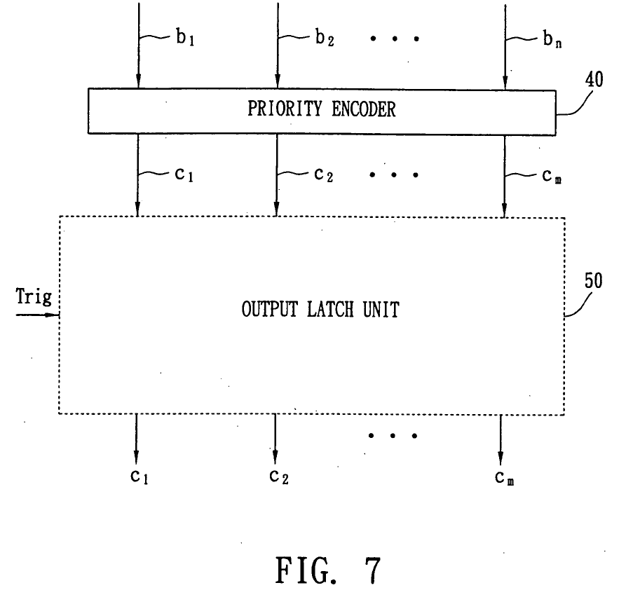

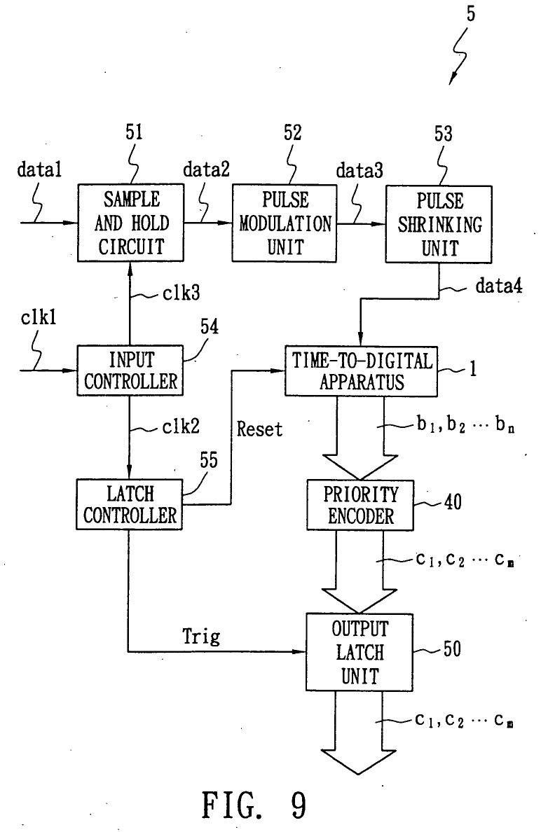

Referring to FIG. 7, the second digital output codes bᵢ are sent to a priority encoder 40 and an output latch unit 50. The priority encoder 40 converts the second digital output codes bᵢ stored in the latch cells 20ᵢ to at least one third digital output code cⱼ (j is a positive integer from 1 to m), where c₁ is the least significant bit (LSB), and cₘ is the most significant bit (MSB). Thus the third digital output codes cⱼ are representative of a binary code. The output latch unit 50 is used to store the third digital output codes cⱼ, and to output the third digital output codes cⱼ after receiving a trigger signal Trig from the latch controller 55 (refer to FIG. 9).

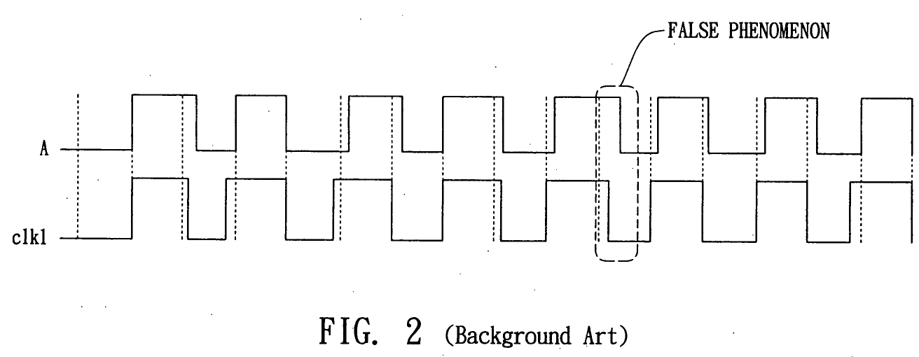

Referring to FIG. 2 again, this shows a measurement method of jitter signals of prior arts. A first clock signal clk1 of a frequency f is utilized to measure the jitters of a high-speed data signal A of the same frequency f. If the accuracy of the first clock signal clk1 is required to be within 2×10⁻¹² second, the silicon germanium process should be used to fabricate the clock generator. The first clock signal clk1 of high-speed which is currently generated by a silicon-processed clock generator itself usually produces jitters, and causes jitter aliasing with the jitters of high-speed data signal A (area of false phenomenon in FIG. 2). Therefore, this will reduce the accuracy of jitter measurement.

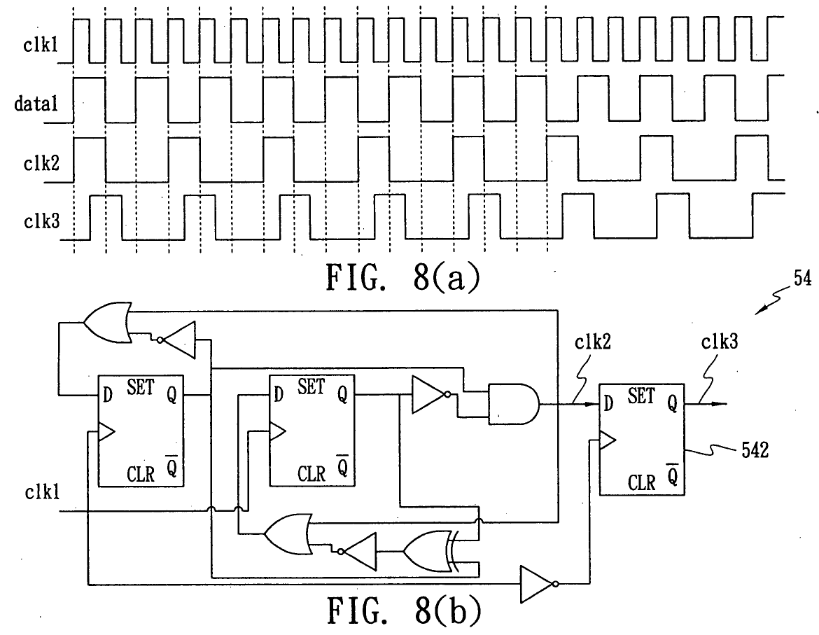

Referring to FIG. 8(a), a third clock signal clk3 of frequency f/3 is used to measure the jitter of a first signal to be tested “data1” of frequency f. Like a technique of photography, the high level period of the third clock signal clk3 is utilized to cover the rising and falling edges of the signal “data1” to eliminate the issue of jitter aliasing. The third clock signal clk3 can be obtained by converting the first clock signal clk1 to the second clock signal clk2, which then passes a D-FF (D type flip-flop). An embodiment of implementing the circuit of the third clock signal clk3 is shown in FIG. 8(b).

The following describes two embodiments of the jitter-measuring apparatus by using the time-to-digital conversion apparatus 1 of the present invention.

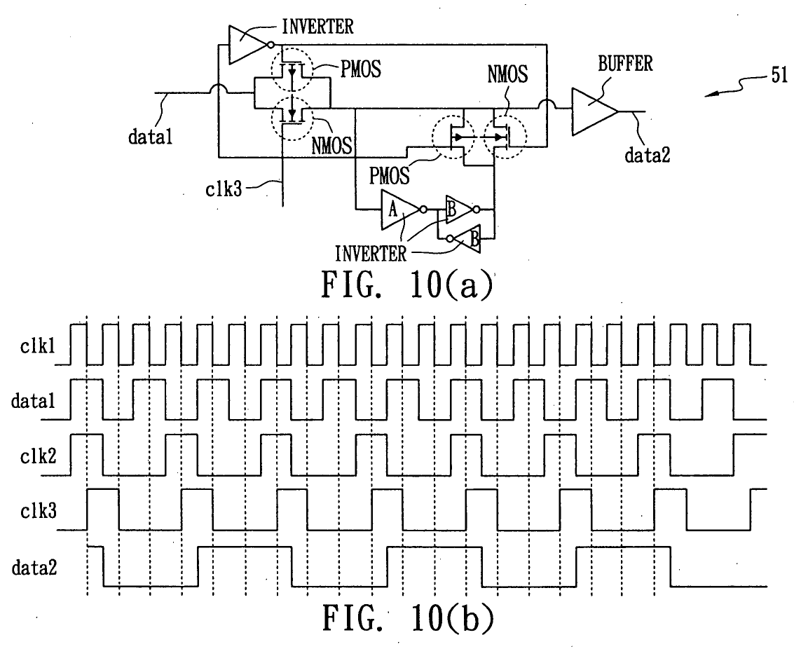

FIG. 9 is a block diagram of the first embodiment of the jitter-measuring apparatus 5 of the present invention. The jitter-measuring apparatus 5 comprises the aforementioned time-to-digital conversion apparatus 1 and an input controller 54 to measure a cycle-to-cycle jitter of a signal. A first clock signal clk1 of frequency f is fed to the input controller 54, and the input controller 54 converts the first clock signal clk1 to a second clock signal clk2 of frequency f/k, where k is an odd integer (k=3 in current embodiment) and to a third clock signal clk3 of frequency f/k with a time delay to the second clock signal clk2 (refer to FIG. 8(a)). A first signal to be tested data1 with a pulse width w1 enters a sample and hold circuit 51 and is converted to a second signal data2 with a pulse width w2 by operating with the third clock signal clk3. FIG. 10(a) discloses an embodiment of a sample and hold circuit 51, which uses the first signal data1 and the third clock signal clk3 as input signals to generate the second signal data2. In a preferred embodiment of the sample and hold circuit 51, the size of inverter A is larger than those of inverters B, with a view to improving the stability of the sample and hold circuit 51. The operation of the sample and hold circuit 51 is described in details as follows. When the level of the third clock signal clk3 is high, the output (i.e., data2) of the sample and hold circuit 51 is the first signal data1. When the level of the third clock signal clk3 is low, the output of the sample and hold circuit 51 remains as the level of the second signal data 2 at that time. FIG. 10(b) is a timing chart of clk1, clk2, clk3, data1 and data2.

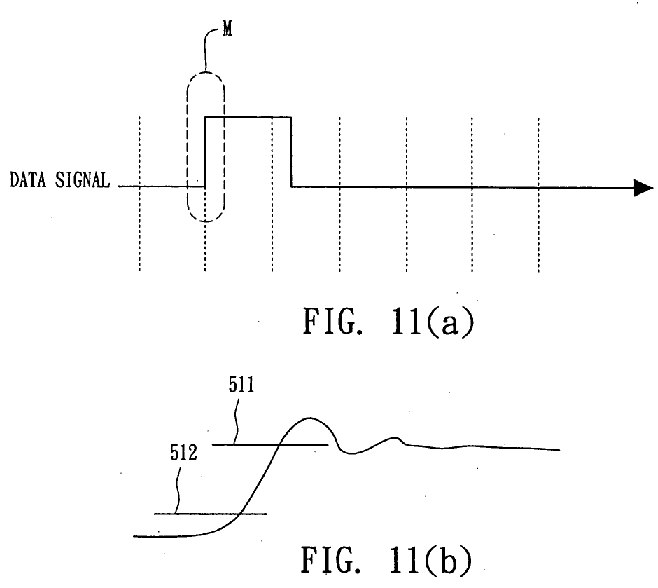

Level transmission of a digital signal is not purely a transmission from low to high or from high to low (FIG. 11(a)). Actually, the level transmission of a data signal changing from “0” to “1” (or from “1” to “0”) is shown in FIG. 11(b), which is a magnification of M area of FIG. 11(a). The slopes of rising and falling edges of the data signal affect the slopes of rising and falling edges 11 in the corresponding eye diagram 15, and thus affect the cycle-to cycle jitter. In general, the sampling points of voltage level from “0” to “1” or from “1” to “0” could be chosen as high or low boundary detection thresholds 511, 512.

The output signal (i.e., data2) of the sample and hold circuit 51 is sent to and modulated by a pulse modulation unit 52 to generate a third signal data3 with a pulse width w3.

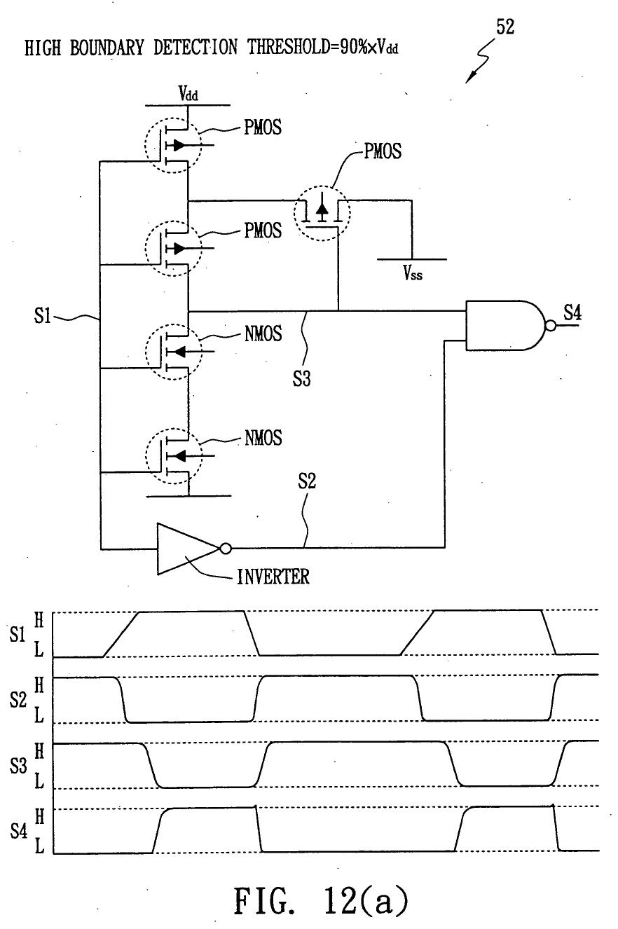

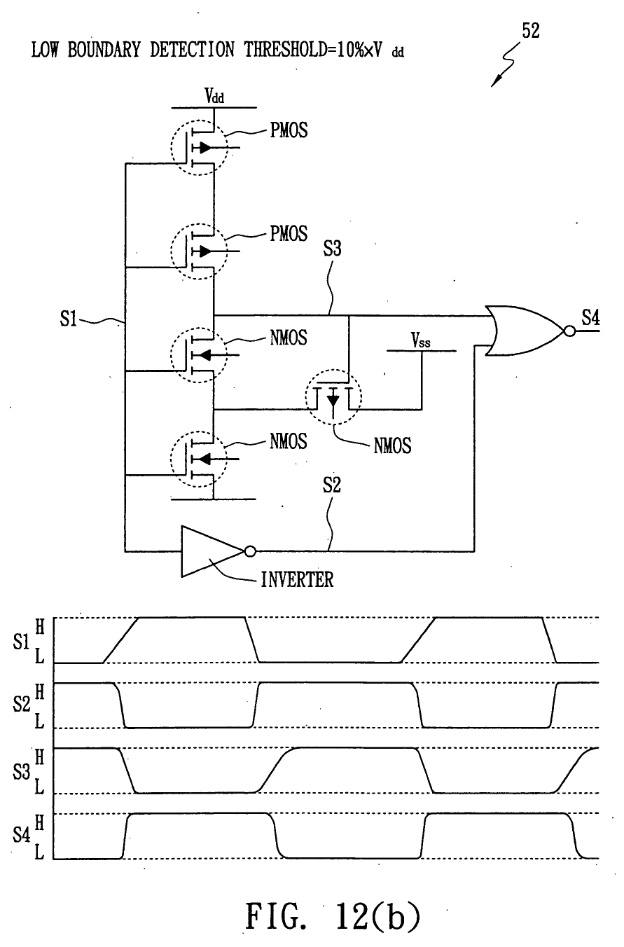

FIG. 12(a) and FIG. 12(b) are two embodiments of the pulse modulation unit 52. The embodiment of FIG. 12(a) utilizes the design of high boundary detection threshold 511 equal to 90% of the power source V_{dd}, while the embodiment in FIG. 12(b) utilizes the design of low boundary detection threshold 512 equal to 10% of the power source V_{dd}. In general, the high and low boundary detection thresholds 511, 512 are set to larger than 80%, lower than 20% of the power source V_{dd}, respectively. After comparison with the timing charts in FIG. 12(a) and FIG. 12(b), it is found that the pulse width of output signal S4 in FIG. 12(b) is larger than that in FIG. 12(a), when both embodiments are fed with the same input signal S1.

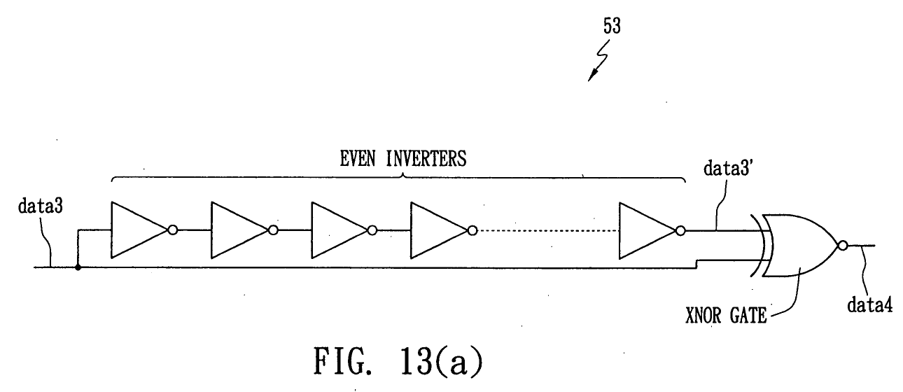

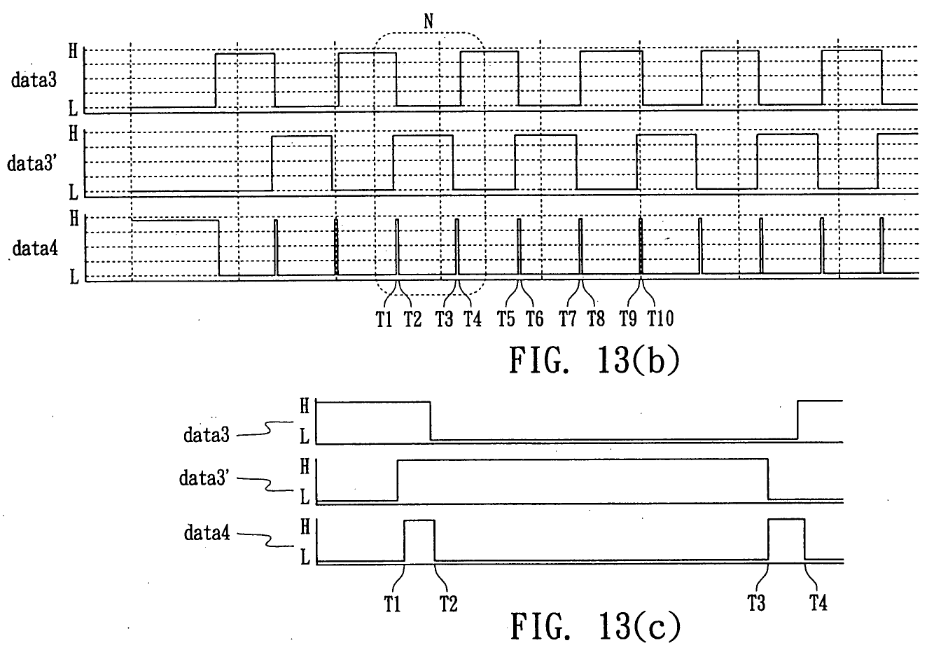

The width of the jitter we measure, in general, is in the order of Pico (10⁻¹²) second, and the information regarding the jitter is implicit in rising and falling edges of a pulse signal. Therefore, a pulse shrinking unit 53 is used to reduce the pulse width of the output signal (i.e., data 3) of the pulse modulation unit 52 to generate a fourth signal data4 with a pulse width w4, where the pulse width w4 includes the jitter information. FIG. 13(a) is an embodiment of the pulse shrinking unit 53. The pulse shrinking unit 53 comprises even inverters cascaded to generate a signal data3′ with a time delay to the third signal data3, and then both the signal data3′ and the third signal data3 are connected to an XNOR (exclusive-NOR) gate to generate the fourth signal data4. FIG. 13(b) shows a timing chart of data3, data3′ and data4. FIG. 13(c) is a magnification of N area of FIG. 13(b). The pulse width w4 of the fourth signal data4 is obviously smaller than the pulse width w3 of the third signal data3, and thus the operation of the pulse width w4 in the time-to-digital conversion apparatus 1 requires less numbers of shrinking cells 10ᵢ. As a result, the signal processing is speeded up and the hardware cost is reduced.

Then the fourth signal data4 (equivalent to a0 in FIG. 3) enters the time-to-digital conversion apparatus 1, and is converted to at least one second digital output code bᵢ (i: a positive integer from 1 to n). The second digital output codes bᵢ are expressed in a thermometer code. After that, the priority encoder 40 converts the second digital output codes bᵢ to at least one third output code cⱼ (j is a positive integer from 1 to m), which is outputted by the output latch unit 50. The operating principles of the time-to-digital conversion apparatus 1, the priority encoder 40 and the output latch unit 50 were described previously, and thus are omitted here.

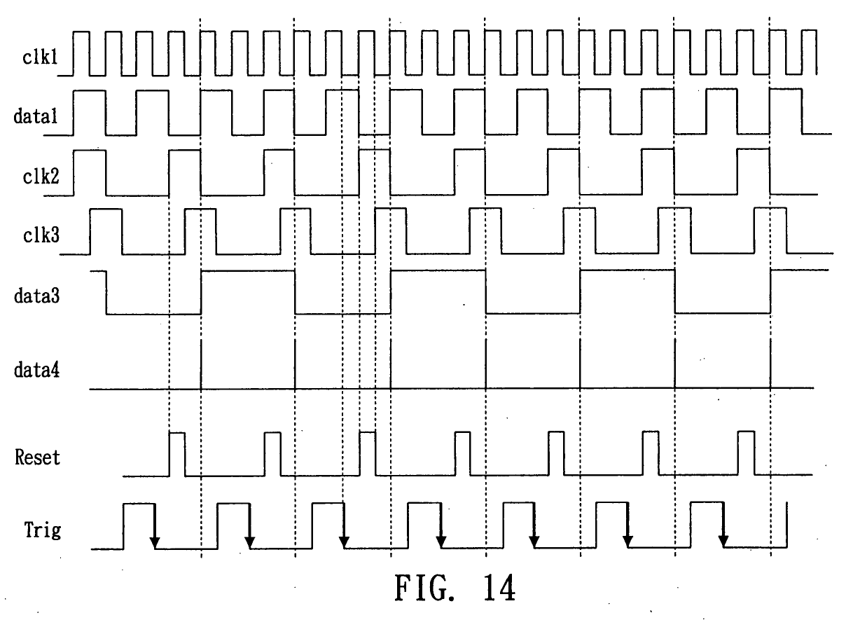

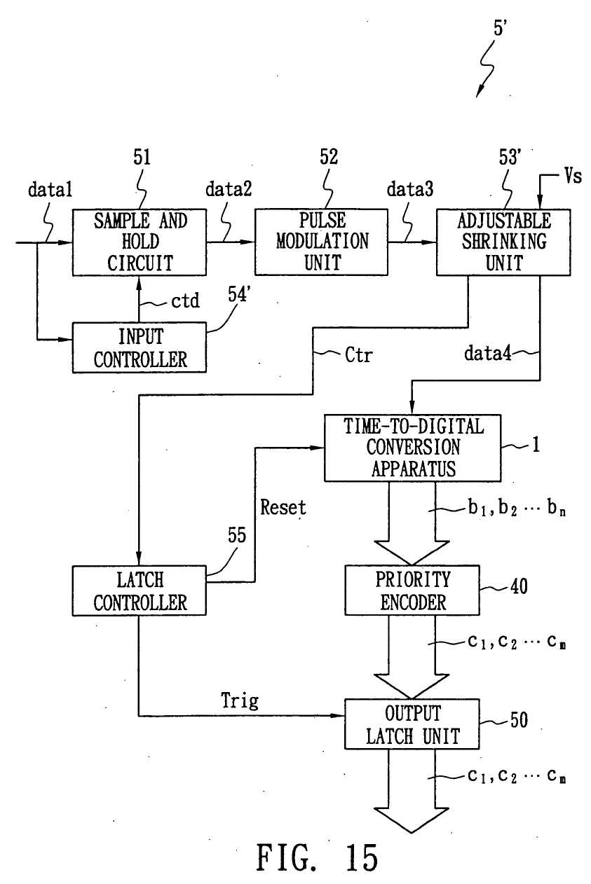

FIG. 14 shows a timing chart of clk1, clk2, clk3, data3, data4, reset signal Reset and trigger signal Trig. The latch controller 55 receives the second clock signal clk2 from the input controller 54 and then generates a reset signal Reset, which is sent to the latch cells 20ᵢ in the time-to-digital conversion apparatus 1 (refer to FIG. 9 and FIG. 3). When a plurality of D-FFs (D type flip-flop) are used as the latch cells 20ᵢ, the reset signal Reset is sent to the CLR port of each D-FF to clear the signal data generated previously inside the D-FF. The pulse shrinking unit 53 receives the third signal data3 and generates the fourth signal data4. The fourth signal data4, generated at instances T1, T4, T8 and T8, include the information regarding the jitter of rising edge of the third signal data3. Similarly, the fourth signal data 4, generated at instances T2, T3, T6 and T7, include the information regarding the jitter of falling edge of the third signal data3 (refer to FIG. 13(b) and 13(c)). After being treated by the time-to-digital conversion apparatus 1, the fourth signal data4 passes the priority encoder 40 and then is stored in the output latch unit 50. So far, the information stored in the output latch unit 50 is at least one third digital output code cⱼ, which also can be treated as a binary code. After the trigger signal Trig from the latch controller 55 is sent to the output latch unit 50, the third digital output codes cⱼ (i.e., the binary code) are outputted. Hence, the product of the binary code and the resolution r represents the pulse width of the fourth signal data4 at that instant, that is, the time width of cycle-to-cycle jitter of the fourth signal data4 at that instant.

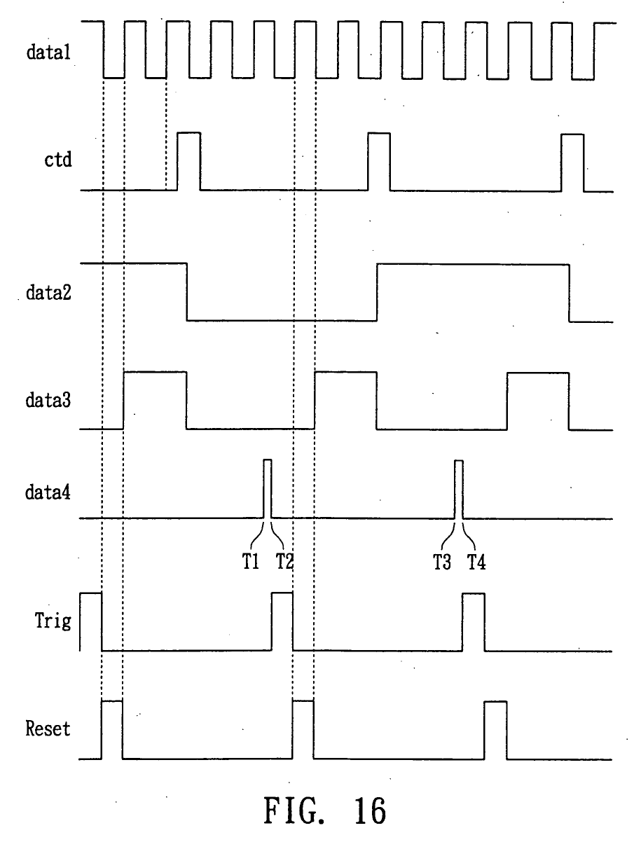

FIG. 15 is a block diagram of the second embodiment of the jitter-measurement apparatus 5′ of the present invention. The jitter-measurement apparatus 5′ comprises the aforementioned time-to-digital conversion apparatus 1 and an input controller 54′ to measure a cycle-to-cycle jitter of a signal. In the second embodiment, no clock signal is required for the operation of the jitter-measurement apparatus 5′. In the second embodiment, the sample and hold circuit 51, pulse modulation unit 52, the time-to-digital conversion apparatus 1, the priority encoder 40, the output latch unit 50 and the latch controller 55 are identical to those in the first embodiment. A first signal data1, of frequency f, is fed to an input controller 54′, and the input controller 54′ converts the first signal data1 to an S/H control signal ctd of frequency f/k, where k is an odd integer (k=9 in the current embodiment), with a time delay to the first signal. At the same time, the first signal data1 is fed to a sample and hold circuit 51 (refer to FIG. 10(a), where clk3 is replaced with ctd in the current embodiment) and is converted to a second signal data2 with a pulse width w2 by operating with the S/H control signal ctd. The output signal (i.e., data2) of the sample and hold circuit 51 is sent to a pulse modulation unit 52 (refer to FIG. 12(a) or FIG. 12(b)) and is modulated to generate a third signal data3 with a pulse width w3. After that, an adjustable pulse shrinking unit 53′ is used to reduce the pulse width w3 of the output data (i.e., data3) of the pulse modulation unit 52 to a fourth signal data4 with a pulse width w4, where the pulse width w4 includes the jitter information. FIG. 16 shows the timing chart of signals data1, data2, data3, data4, ctd, reset signal Reset and trigger signal Trig, which are regarding the second embodiment of the jitter-measurement apparatus 5′ of the present invention, in which both of the rising edges of the reset signal Reset and the trigger signal Trig follow the rising edge of the third signal data3.

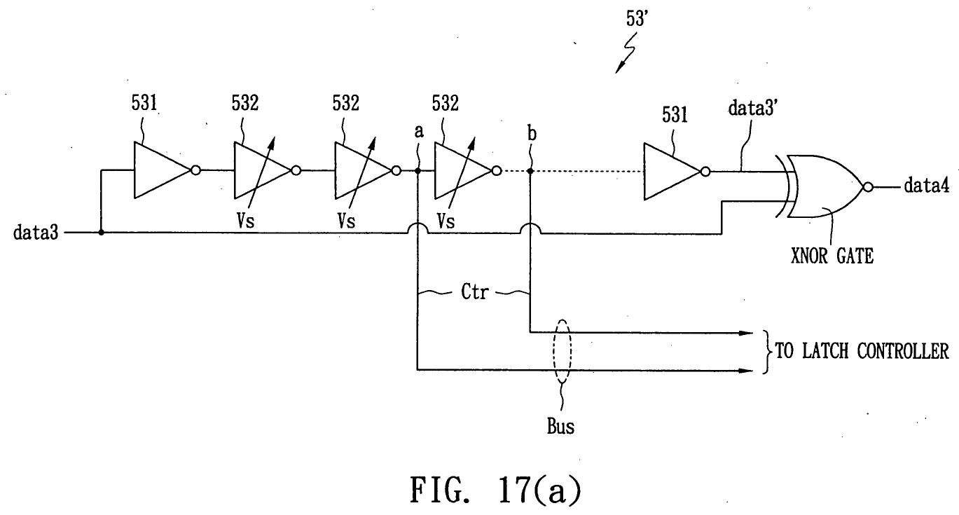

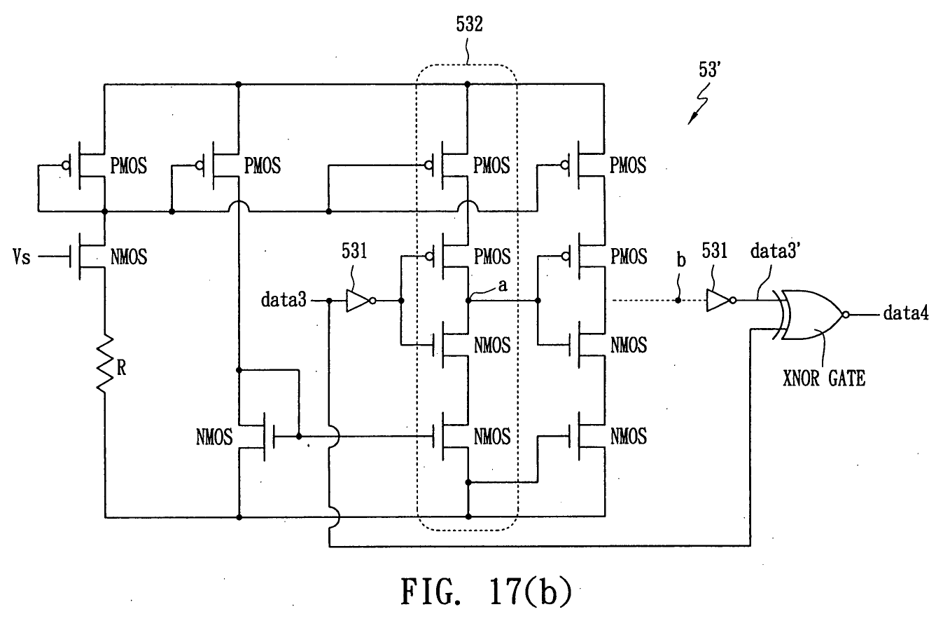

FIG. 17(a) illustrates one embodiment of the adjustable pulse shrinking unit 53′ and FIG. 17(b) is a circuit of one embodiment of the adjustable pulse shrinking unit 53′ in FIG. 17(a). The adjustable pulse shrinking unit 53′ comprises an inverter string and an XNOR logic gate. The inverter string, comprising some even number of inverters disposed in series, includes (1) two fixed inverters 531 disposed at the opposing ends of the inverter string; and (2) an even number of adjustable inverters 532 disposed between the two fixed inverters 531. The inverter string receives the third signal data3 to generate a signal data3′ with a time delay to the third signal data3; the time delay is adjustable by a second control signal Vs. Then, both the signal data3′ and the third signal data3 are fed to the XNOR logic gate to generate a fourth signal data4 with a pulse width w4. Thus, the pulse width w4 is adjustable by the second control signal Vs. In FIG. 17(a), a first control signal Ctr is sent to a latch controller 55 (refer to FIG. 15) by a bus Bus connected to nodes a and b to generate the trigger signal Trig. The number of the adjustable inverters between nodes a and b should be odd to reduce the error due to pulse shrinking. In the current embodiment, the bus Bus comprises only two signal cables, although it could comprise more signal cables according to applications. That is, the number of nodes is not limited to two, and depends on the applications.

Referring back to FIG. 15, the fourth signal data4 (equivalent to a₀ in FIG. 3) enters the time-to-digital conversion apparatus 1 and is converted to at least one second digital output code bᵢ (i: a positive integer from 1 to n). In the current embodiment, the resolution r is adjustable by a third control signal Vc (refer to FIG. 4). The second digital output codes bᵢ are expressed in a thermometer code. Then, the priority encoder 40 converts the second digital output code bᵢ to at least one third output code cⱼ (j is a positive integer from 1 to m), which is outputted by the output latch unit 50. The latch controller 55 receives the first control signal Ctr from the adjustable pulse shrinking unit 53′ and then sends the reset signal Reset to the latch cells 20ᵢ of the time-to-digital conversion apparatus 1 (refer to FIG. 15 and FIG. 3). When a plurality of D-FFs (D type flip-flop) are used as the latch cells 20ᵢ, the reset signal Reset is sent to the CLR port of each D-FF to clear the signal data generated previously inside the D-FFs. The adjustable pulse shrinking unit 53′ receives the third signal data3 and generates the fourth signal data4. The fourth signal data4, generated at instances T1 and T4, contain the information regarding the jitter of the rising edge of the third signal data3. Similarly, the fourth signal data4, generated at instances T2 and T3, contain the information regarding the jitter of falling edge of the third signal data3 (refer to FIG. 16). After being treated by the time-to-digital conversion apparatus 1, the fourth signal data4 passes the priority encoder 40 and then is stored in the output latch unit 50. So far, the information stored in the output latch unit 50 is at least one third digital output code cⱼ, which can also be treated as a binary code. After the trigger signal Trig from the latch controller 55 is sent to the output latch unit 50, the third digital output codes cⱼ (i.e., the binary code) are outputted. Hence, the product of the binary code and the resolution r represents the pulse width of the fourth signal data4 at that instance, that is, the time width of cycle-to-cycle jitter of the fourth signal data4 at that instance.

The above-described embodiments of the present invention are intended to be illustrative only. Numerous alternative embodiments may be devised by persons skilled in the art without departing from the scope of the following claims.

What is claimed is:

1. A time-to-digital conversion apparatus, which is operated with a clock signal, to convert a signal to be tested to a digital code, comprising:
a shrinking cell group converting the signal to be tested to a plurality of first digital output codes, the shrinking cell group including a plurality of shrinking cells connected in series to form a multi-stage shrinking cell, each of the shrinking cells generating one of the first digital output codes; and
a latch cell group including a plurality of latch cells, each latch cell being connected to the corresponding shrinking cell, each latch cell receiving and latching the first digital output code to generate a second digital output code.

2. The time-to-digital conversion apparatus according to claim 1, wherein a pulse width of the signal to be tested is reduced by a resolution after the signal to be tested passes each shrinking cell until the pulse width cannot drive the next shrinking cell.

3. The time-to-digital conversion apparatus according to claim 2, wherein the shrinking cell comprises:
a first CMOS inverter receiving an input signal to generate a middle signal;
a second CMOS inverter receiving the middle signal to generate an output signal; and
an adjustment unit receiving the middle signal and the output signal and using a control signal to adjust the resolution.

4. The time-to-digital conversion apparatus according to claim 3, wherein the input signal of the first-stage shrinking cell is the signal to be tested.

5. The time-to-digital conversion apparatus according to claim 3, wherein the adjustment unit comprises:
a PMOS having a first terminal to receive the output signal, a second terminal to receive a power source, and a third terminal to receive the middle signal; and
an NMOS having a fourth terminal connected to the first terminal to receive the output signal, a fifth terminal connected to the third terminal to receive the middle signal, and a sixth terminal to receive the control signal.

6. The time-to-digital conversion apparatus according to claim 5, wherein the latch cell receives the corresponding first digital output code and outputs a signal with the same level as that of the corresponding first digital output code.

7. The time-to-digital conversion apparatus according to claim 5, wherein the latch cell is a flip-flop including a clock port connected to the corresponding first digital output code, and an input port connected to the power source.

8. The time-to-digital conversion apparatus according to claim 1, wherein the second digital output code is expressed in a thermometer code.

9. The time-to-digital conversion apparatus according to claim 1, wherein the second digital output code is conditioned by a priority encoder to convert the second digital output code to at least one third digital output code which is stored in an output latch unit and is outputted whenever the output latch unit receives a trigger signal.

10. The time-to-digital conversion apparatus according to claim 9, wherein the third digital output code is a binary code.

11. A jitter-measuring apparatus, comprising:
an input controller dividing the frequency of a first clock signal by an odd number down to be a second clock signal, and generating a third clock signal with a time delay to the second clock signal;
a sample and hold circuit converting a first signal with a first pulse width to a second signal with a second pulse width in the light of the level of the third clock signal;
a pulse modulation unit converting the second signal to a third signal with a third pulse width by operating with a threshold voltage;
a pulse shrinking unit converting the third signal with the third pulse width to a fourth signal with a fourth pulse width;
a time-to-digital apparatus converting the fourth signal to at least one second digital output code; and
a latch controller using the second clock signal from the input controller to generate a reset signal to the time-to-digital conversion apparatus and generate a trigger signal.

12. The jitter-measuring apparatus according to claim 11, wherein the threshold voltage is less than 20% or larger than 80% of a power source.

13. The jitter-measuring apparatus according to claim 11, wherein the pulse shrinking unit comprises:
inverters of even number connected in series, receiving the third signal; and
an XNOR logic gate connected to the end of the inverters, receiving the third signal to generate the fourth signal.

14. The jitter-measuring apparatus according to claim 11, wherein the time-to-digital apparatus comprises:
a shrinking cell group converting the fourth signal to a plurality of first digital output codes, the shrinking cell group including a plurality of shrinking cells connected in series to form a multi-stage shrinking cell, each of the shrinking cells generating one of the first digital output codes; and
a latch cell group including a plurality of latch cells, each latch cell being connected to the corresponding shrinking cell, each latch cell receiving and latching the first digital output code to generate the second digital output code.

15. The jitter-measuring apparatus according to claim 14, wherein a pulse width of the fourth signal is reduced by a resolution after the fourth signal passes each shrinking cell until the pulse width cannot drive the next shrinking cell.

16. The jitter-measuring apparatus according to claim 15, wherein the shrinking cell comprises:
a first CMOS inverter receiving an input signal to generate a middle signal;
a second CMOS inverter receiving the middle signal to generate an output signal; and
an adjustment unit receiving the middle signal and the output signal and using a control signal to adjust the resolution.

17. The jitter-measuring apparatus according to claim 16, wherein the input signal of the first-stage shrinking cell is the fourth signal.

18. The jitter-measuring apparatus according to claim 16, wherein the adjustment unit comprises:
a PMOS having a first terminal to receive the output signal, a second terminal to receive a power source, and a third terminal to receive the middle signal; and
an NMOS having a fourth terminal connected to the first terminal to receive the output signal, a fifth terminal connected to the third terminal to receive the middle signal, and a sixth terminal to receive the control signal.

19. The jitter-measuring apparatus according to claim 18, wherein the latch cell receives the corresponding first digital output code and outputs a signal with the same level as that of the corresponding first digital output code.

20. The jitter-measuring apparatus according to claim 18, wherein the latch cell is a flip-flop including a clock port connected to the corresponding first digital output code, and an input port connected to the power source.

21. The jitter-measuring apparatus according to claim 11, wherein the second digital output code is expressed in a thermometer code.

22. The jitter-measuring apparatus according to claim 15, wherein the second digital output code is conditioned by a priority encoder to convert the second digital output code to at least one third digital output code which is stored in an output latch unit and is outputted whenever the output latch unit receives the trigger signal.

23. The jitter-measuring apparatus according to claim 22, wherein the trigger signal comes from the latch controller.

24. The jitter-measuring apparatus according to claim 22, wherein the third digital output code is a binary code.

25. The jitter-measuring apparatus according to claim 24, wherein a pulse width of the fourth signal is reduced by the resolution after the fourth signal passes each shrinking cell until the pulse width cannot drive the next shrinking cell, and the product of the binary code and the resolution represents the time width of cycle-to-cycle jitter of the first signal.

26. A jitter-measuring apparatus, comprising:
an input controller converting a first signal to a sample and hold control signal;
a sample and hold circuit converting the first signal to a second signal with a second pulse width by operating with the sample and hold control signal;
a pulse modulation unit converting the second signal to a third signal with a third pulse width by operating with a threshold voltage;
an adjustable pulse shrinking unit reducing the third pulse width to generate a fourth signal with a fourth pulse width;
a time-to-digital conversion apparatus converting the fourth signal to at lease one second digital output code; and
a latch controller receiving a first control signal from the adjustable pulse shrinking unit to generate a reset signal to the time-to-digital conversion apparatus and generate a trigger signal.

27. The jitter-measuring apparatus according to claim 26, wherein the threshold voltage is less than 20% or larger than 80% of a power source.

28. The jitter-measuring apparatus according to claim 26, wherein the adjustable pulse shrinking unit comprises:
an inverter string comprising some even number of inverters disposed in series, receiving the third signal, including two fixed inverters disposed at opposing ends of the inverter string and an even number of adjustable inverters disposed between the two fixed inverters; and
an XNOR logic gate receiving the third signal and the output of the inverter string to generate the fourth signal, wherein the fourth pulse width is adjustable by a second control signal.

29. The jitter-measuring apparatus according to claim 26, wherein the time-to-digital conversion apparatus comprises:
a shrinking cell group converting the fourth signal to a plurality of first digital output codes, the shrinking cell group including a plurality of shrinking cells connected in series to form a multi-stage shrinking cell, each of the shrinking cells generating one of the first digital output codes; and
a latch cell group including a plurality of latch cells, each latch cell being connected to the corresponding shrinking cell, each latch cell receiving and latching one of the first digital output codes to generate the second digital output code.

30. The jitter-measuring apparatus according to claim 29, wherein a pulse width of the fourth signal is reduced by a resolution after the fourth signal passes each shrinking cell until the pulse width cannot drive the next shrinking cell.

31. The jitter-measuring apparatus according to claim 30, wherein the shrinking cell comprises:
a first CMOS inverter receiving an input signal to generate a middle signal;
a second CMOS inverter receiving the middle signal to generate an output signal; and
an adjustment unit receiving the middle signal and the output signal and using a third control signal to adjust the resolution.

32. The jitter-measuring apparatus according to claim 31, wherein the latch cell receives the corresponding first digital output code and outputs a signal with the same level as that of the corresponding first digital output code.

33. The jitter-measuring apparatus according to claim 31, wherein the latch cell is a flip-flop including a clock port receiving the corresponding first digital output code, and an input port connected to a power source.

34. The jitter-measuring apparatus according to claim 26, wherein the second digital output code is expressed in a thermometer code.

35. The jitter-measuring apparatus according to claim 31, wherein the second digital output code is conditioned by a priority encoder to convert the second digital output code to at least one third digital output code which is stored in an output latch unit and is outputted whenever the output latch unit receives the trigger signal.

36. The jitter-measuring apparatus according to claim 35, wherein the trigger signal is generated by the latch controller.

37. The jitter-measuring apparatus according to claim 35, wherein the third digital output code is expressed as a binary code, and the product of the binary code and the resolution represents the pulse width of cycle-to-cycle jitter of the first signal.

38. A method of time-to-digital conversion comprising the steps of:
shrinking a pulse width of a signal to be tested successively by a resolution to generate a plurality of first digital output codes; and
latching the plurality of the first digital output codes to generate a plurality of second digital output codes.

39. The method of time-to-digital conversion according to claim 38, wherein the plurality of second digital output codes are expressed in thermometer codes.

40. The method of time-to-digital conversion according to claim 38, further comprising the step of converting the plurality of second digital output codes to at least one third digital output code in a binary code.

41. The method of time-to-digital conversion according to claim 40, wherein the third digital output code is outputted by a trigger signal.

42. The method of time-to-digital conversion according to claim 38, wherein the pulse width of the signal to be tested covers the edges of another signal to be tested.
